(19) United States
(12) Patent Application Publication
(10) Pub. No.: US 2010/0040438 A1
(43) Pub. Date: Feb. 18, 2010

(54) System and Method for Transferring Packaged Semiconductors Between Storage Mediums

(76) Inventors: Hung-Yi Lee, Taipei Hsien (TW); Hsien-Shen Chen, Taipei Hsien (TW); Johns Lee, Taipei Hsien (TW); Joe Chou, (US)

Correspondence Address: TEXAS INSTRUMENTS INCORPORATED, P O BOX 655474, M/S 3999, DALLAS, TX, 75265, US

(21) Appl. No.: 12/192,599

(22) Filed: Aug. 15, 2008

(51) Int. Cl. H01L 21/677

(52) U.S. Cl. 414/217.1

(57) ABSTRACT

Systems and methods are disclosed that can be employed in transferring a plurality of packaged semiconductors. The system comprises a first input station configured to receive one or more storage mediums of a first type configured to store packaged semiconductors. A second input station is configured to receive one or more storage mediums of a second type configured to store packaged semiconductors. A differential pressure supply provides a differential pressure that moves packaged semiconductors between a given storage medium of the first type and a given storage medium of the second type.

### TECHNICAL FIELD

The present invention relates to packaged semiconductors and more particularly to a system and method for transferring packaged semiconductors between storage mediums.

### BACKGROUND

After packaged semiconductors (e.g., integrated circuit chips) are manufactured, the packaged semiconductors are typically tested rigorously to reduce the failure rate of the packaged semiconductors. The testing can include, for example, a baking (e.g., heating) process that heats the packaged semiconductors in an oven per requirements of a moisture disorder. The heating can, for example, simulate an aging process. Such a baking typically requires that the packaged semiconductors be stored in a heat resistant (e.g., metallic) storage medium during the baking process. Some ovens employed for the baking process can receive a plurality (e.g., a rack) of the heat resistant storage mediums such that many packaged semiconductors can be baked at the same time.

Packaged semiconductors are often stored in elongated plastic tubes after the packaged semiconductors are manufactured, before and after the testing. During testing, the packaged semiconductors are transferred from a plastic tube to the heat resistant storage medium. Typically, the packaged semiconductors are transferred manually by an operator. As an example, the operator aligns the plastic tube with the heat resistant storage medium and tilts the plastic tube and the heat resistant storage medium such that gravity drives the packaged semiconductors from the plastic tube to the heat resistant storage medium through a supporting exchanger that aids in aligning the plastic tube and the heat resistant storage medium. Additionally, in a similar manner (e.g., manual tilting of the plastic tube and heat resistant storage medium), the packaged semiconductors are typically transferred back into the plastic tube after the baking process.

### SUMMARY

One aspect of the invention provides a system for transferring packaged semiconductors. The system comprises a first input station configured to receive one or more storage mediums of a first type configured to store packaged semiconductors. A second input station is configured to receive one or more storage mediums of a second type configured to store packaged semiconductors. A differential pressure supply provides a differential pressure (e.g., force by air-blow) that moves packaged semiconductors between a given storage medium of the first type and a given storage medium of the second type.

Another aspect of the invention provides a system for transferring a plurality of packaged semiconductors. The system comprises a first means for storing the plurality of packaged semiconductors. The system also comprises a second means for storing the plurality of packaged semiconductors. The system further comprises means for providing a differential pressure that transfers the plurality of packaged semiconductors from the first means for storing to the second means for storing.

Yet another aspect of the invention provides a method for transferring a plurality of packaged semiconductors. A plurality of first packaged semiconductor storage mediums are loaded at a first input station, thereby forming a first input stack. The first packaged storage mediums contain the plurality of semiconductors. A plurality of second packaged semiconductor storage mediums are loaded at a second input station, thereby forming a second input stack. The plurality of packaged semiconductors are transferred from the plurality of first semiconductor storage mediums to the plurality of second packaged semiconductor storage mediums with an application of a differential pressure.

### BRIEF DESCRIPTION OF THE DRAWINGS

FIG. 1 illustrates an example of a top view of a system for transferring integrated circuit chips between storage mediums in accordance with an aspect of the invention.

FIG. 2 illustrates an example of a side view of the system illustrated in FIG. 1 in accordance with an aspect of the invention.

FIG. 3 illustrates an example of a plastic tube for storing packaged semiconductors in accordance with an aspect of the invention.

FIG. 4 illustrates an example of a metallic magazine for storing packaged semiconductors in accordance with an aspect of the invention.

FIG. 5 illustrates an example of a top view of a buffer track in accordance with an aspect of the invention.

FIG. 6 illustrates a cross sectional view of the buffer track illustrated in FIG. 7, taken along line 6-6.

FIG. 7 illustrates a flow chart of a methodology for transferring packaged semiconductors between plastic tubes and metallic magazines in accordance with an aspect of the invention.

### DETAILED DESCRIPTION

Packaged semiconductors often require a transfer between storage mediums for processing and shipping. The present invention employs a pressure differential to move packaged semiconductors between storage mediums. The employment of a pressure differential facilitates the prevention of bent leads and cracked/chip rejection caused by manual transfer of packaged semiconductors between storage mediums.

In one aspect of the invention, a pressure differential transfer system is employed to transfer packaged semiconductors between elongated plastic tubes and bake racks, which can be referred to as metallic magazines. Each metallic magazine can have, for example, a plurality of compartments, wherein each compartment can receive and store packaged semiconductors. A pressure differential transfer system can be configured to receive a stack of the elongated tubes at a tube input station, and a stack of metallic magazines at a magazine input station. The pressure differential transfer system can be configured to align an elongated tube and a compartment of a metallic magazine with a guide (e.g., a buffer track) such that the pressure differential transfer system can apply a pressure differential between a first and second end of a given one of the elongated tubes and metallic magazines to move packaged semiconductors to the other of the elongated tube and metallic magazine.

As one example, to facilitate the movement of the packaged semiconductors, air or vacuum pressure can be applied to an end of a given one of the elongated tubes and metallic magazines. Alternatively, vacuum pressure can be applied to an end of a given one of the elongated tubes and the metallic magazines concurrently with an application of air pressure to an end of the other of the elongated tube and metallic magazine. Accordingly, packaged semiconductors can be transferred between tubes and magazines without gravitational assistance. The pressure differential transfer system can be configured to index the tubes and magazines in a manner as to transfer packaged semiconductors from one or more tubes to one or more compartments of the magazine. The magazine can be employed for oven baking of the packaged semiconductors.

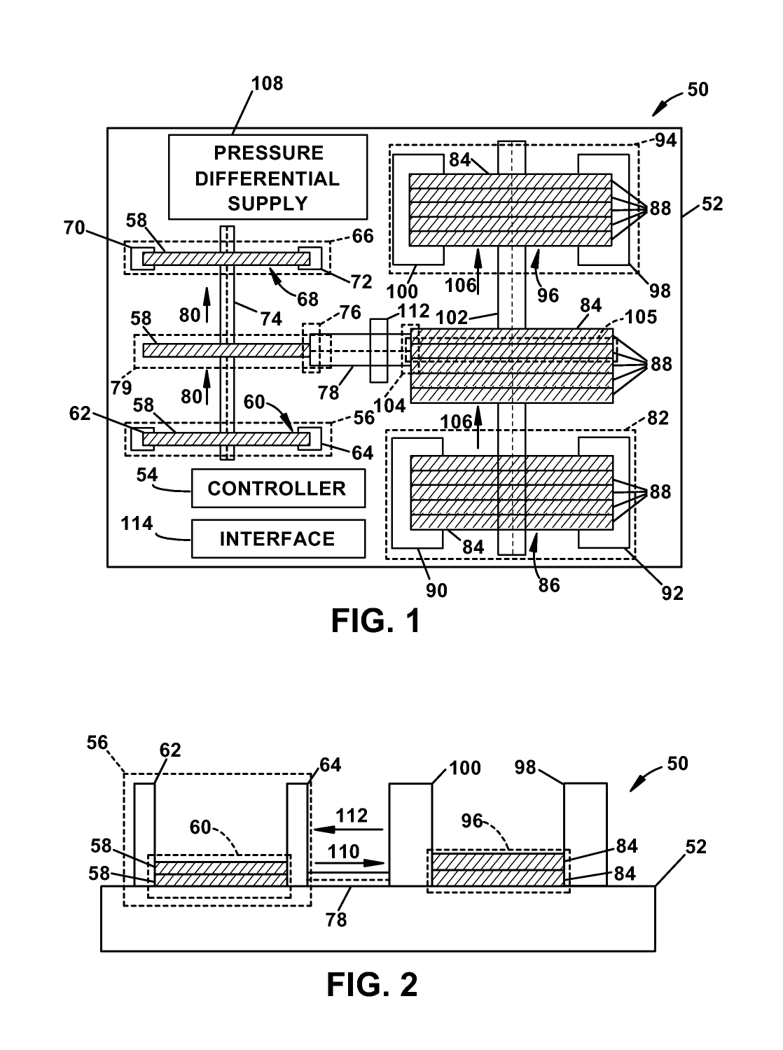

FIGS. 1 and 2 illustrate a system 50 for transferring packaged semiconductors between storage mediums in accordance with an aspect of the invention. The packaged semiconductors can include, for example, integrated circuit chips. The system 50 can be implemented, for example, as a pressure differential transfer system 52 (e.g., a force air-blow differential transfer system). FIG. 1 illustrates a top view of the pressure differential transfer system 52. FIG. 2 illustrates a front view of the pressure differential transfer system 52. For purposes of simplification of explanation, the same reference numbers are employed in FIGS. 1 and 2 to denote the same structure. Moreover, not all of the features of the pressure differential transfer system 52 are illustrated in both FIGS. 1 and 2.

The pressure differential transfer system 52 can include a controller 54 that can be configured to control motors and solenoids associated with the pressure differential transfer system 52. The controller 54 can be implemented, for example, as hardware, software or a combination thereof. The pressure differential transfer system 52 can include, for example, a tube input station 56 configured to receive a stack of elongated tubes 58 (e.g., a semiconductor storage medium) for receiving and storing packaged semiconductors, (hereinafter “tubes” 58), which can be referred to as a tube input stack 60. The tube input stack 60 can include one or more tubes 58. Each tube 58 can be made from a non-conductive material (e.g., plastic). Additionally, one skilled in the art will appreciate that conductive (e.g., metallic) material could be employed as well. The tube input station 56 can include a first pillar 62 and a second pillar 64 for receiving the tube input stack 60, and for holding the tube input stack 60 relatively still. The tube input station 56 can include, for example, a tube lowering mechanism (e.g., a servo motor, a solenoid, etc.) that can lower the tube input stack 60 if a first tube 58 (e.g., the lowest tube 58) is removed (e.g., singulated) from the tube input stack 60. The tube lowering mechanism can be controlled, for example, by the controller 54.

The pressure differential transfer system 52 can also include a tube output station 66 configured in a manner similar to the tube input station 56. The tube output station 66 can be configured to form a stack of tubes 58 at the output station upon receiving a tube 58. The stack of tubes 58 at the tube output station 66 can be referred to as a tube output stack 68. The tube output stack 68 can include one or more tubes 58. The tube output station 66 can include first and second pillars 70 and 72 for holding the tube output stack 68 relatively still. The tube output station 66 can include, for example, a tube stacking mechanism (e.g., a servo motor, a solenoid or the like). The tube stacking mechanism can raise the tube output stack 68 while maintaining a stacked configuration. Typically, the tube output stack 68 is raised in response to the tube output station 66 receiving a tube 58, such that the received tube 58 can be added to the tube output stack 68. The tube stacking mechanism can be controlled, for example, by the controller 54.

A tube indexer 74 can be included to convey (e.g., singulate) tubes 58 from the tube input station 56 to a position proximal to a tube end 76 (e.g., a tube section) of a buffer track 78 and to the tube output station 66. Such a position can be referred to as a tube transfer station 79. The tube indexer 74 can convey tubes 58 in a direction indicated by arrows at 80. The tube indexer 74 can be implemented, for example as a conveyor belt or chain, a push rod, etc. One skilled in the art will appreciate the various structures that can be employed as the tube indexer 74. The tube indexer 74 can be driven, for example, with a motor and/or solenoid controlled by the controller 54.

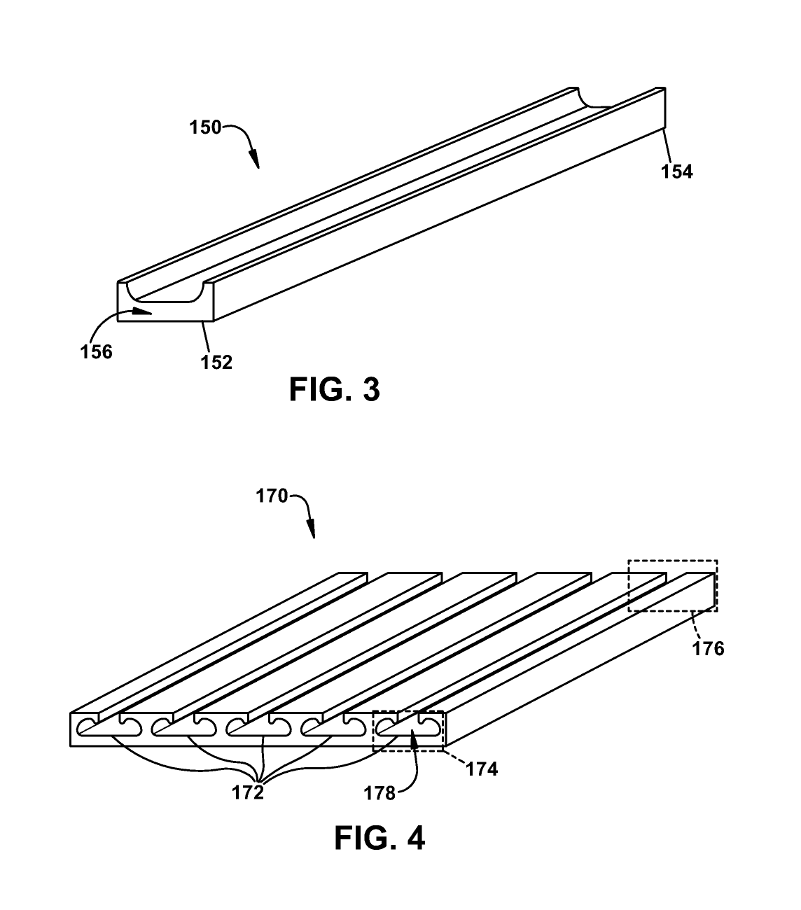

FIG. 3 illustrates an example of a tube 150 (e.g., a plastic tube) employable by the pressure differential transfer system 52 illustrated in FIGS. 1 and 2 in accordance with an aspect of the invention. The tube 150 can have for example, a first end 152 and a second end 154 with a passage 156 from the first end 152 to the second end 154. The tube 150 can receive and store packaged semiconductors in the passage 156. The tube 150 can have a substantially U-shaped cross section. One skilled in the art will appreciate that other shapes of the tube 150 are possible as well.

Referring back to FIGS. 1 and 2, the pressure differential transfer system 52 can also include, for example, a magazine input station 82 configured to receive a stack of packaged semiconductor baking racks (e.g., semiconductor storage mediums), such as magazines 84, (hereinafter “magazines” 84). The stack of magazines 84 received at the magazine input station 82 can be referred to as a magazine input stack 86. The magazine input stack 86 can include one or more magazines 84. Each magazine 84 can be formed, for example with a conductive material such as metallic or alloyed material (e.g., steel). It is to be understood, however, that other materials could be employed as well, such as an insulating material. Each magazine 84 can include one or more compartments 88 for storing packaged semiconductors. In the present example, each magazine 84 includes five compartments 88, although one skilled in the art will appreciate that each magazine 84 can have more or less compartments 88. The magazine input station 82 can include a first pillar 90 and a second pillar 92 for receiving the magazine input stack 86, and for holding the magazine input stack 86 relatively still. The magazine input station 82 can include, for example, a lowering mechanism (e.g., a servo motor, a solenoid, etc.) that can lower the magazine input stack 86. The lowering mechanism can be controlled, for example, by the controller 54. The magazine input stack 86 can be lowered, for example, when a first magazine 84 (e.g., the lowest magazine 84 of the magazine input stack 86) is removed (e.g., singulated) from the magazine input stack 86.

The pressure differential transfer system 52 can also include a magazine output station 94 configured in a manner similar to the tube output station 66. The magazine output station 94 can form a stack of magazines 84, referred to as a magazine output stack 96 in response to receiving a magazine 84. The magazine output station 94 can include first and second pillars 98 and 100 for holding the magazine output stack 96 relatively still. The magazine output station 94 can include, for example, a magazine stacking mechanism (e.g., a servo motor, a solenoid or the like). The magazine stacking mechanism can raise the magazine output stack 96 while maintaining a stacked configuration. The magazine stacking mechanism can be controlled, for example, by the controller 54.

A magazine indexer 102 can be included to convey magazines 84 from the magazine input stack 86 to a position such that a compartment 88 of the magazine 84 is proximal to a magazine end 104 (e.g., a magazine section) of the buffer track 78, and to the magazine output station 94. Such a position can be referred to as a magazine transfer station 105. The magazine indexer 102 can convey the magazines 84 in a direction indicated by arrows at 106. The magazine indexer 102 can be implemented, for example as a conveyor belt or chain, a push rod, etc. One skilled in the art will appreciate the various structures that can be employed as the magazine indexer 102. The magazine indexer 102 can be driven, for example, with a motor and/or solenoid that is controlled by the controller 54.

FIG. 4 illustrates an example of a magazine 170 (e.g., a metallic magazine) employable by the pressure differential transfer system 52 illustrated in FIGS. 1 and 2 in accordance with an aspect of the invention. The magazine includes 5 compartments 172 for receiving and/or storing packaged semiconductors. Each compartment 172 can include a first end 174 and a second end 176. For purposes of simplification of explanation, only the first end 174 and second end 176 of one compartment 172 are marked in detail in FIG. 4. A passage 178 from the first end 174 to the second end 176 can be included to receive and store packaged semiconductors. Each compartment 172 of the magazine 170 can have a substantially U-shaped cross section. One of ordinary skill in the art will appreciate that other shapes of the magazine 170 are also possible.

Referring back to FIGS. 1 and 2, the tube indexer 74 and the magazine indexer 102 can be arranged to provide a first in first out (FIFO) configuration at the tube input station 56 and the magazine input station 82. That is, the tube and magazine indexers 74 and 102 can be configured to convey (e.g., singulate) a tube 58 or a magazine 84 in directions indicated at 80 and 106 in the same order that tubes 58 and magazines 84 are loaded in the tube and magazine input stations 66 and 82.

As mentioned above, the pressure differential transfer system 52 can include a buffer track 78. The buffer track 78 can include the aforementioned tube and magazine ends 76 and 104. The buffer track 78 can be configured to adapt an end of a tube 58 to an end of a compartment of a magazine 84. Thus, the magazines 84 and the tubes 58 can have different dimensions. The buffer track 78 can be implemented, for example, as a duct for guiding packaged semiconductors between the magazines 84 and the tube 58. When a tube 58 and a magazine 84 are positioned at respective tube and magazine transfer stations 79 and 105 of the buffer track 78, a differential pressure (e.g., force by air-blow, air pressure, or vacuum pressure) can be applied from a differential pressure supply 108 (e.g., an air pump, a vacuum, etc.) through the pressure differential transfer system 52 that causes packaged semiconductors to be transferred from the positioned tube 58 to the positioned compartment 88 of the magazine 84 or vice versa along directions indicated by arrows at 110 and 112. The differential pressure supply 108 can be controlled, for example, by the controller 54.

As one example, the differential pressure can be applied to an end of the tube 58 or magazine 84 distal to the buffer track 78. Additionally, it is considered that the differential pressure can be applied to both ends of the tube and the magazine that are distal to the buffer track 78. In such a situation, air pressure could be applied to one end distal to the buffer track 78 (of tube 58 or the magazine 84), while a vacuum pressure can be applied to the other end distal to the buffer track 78. Moreover, control of the amount of differential pressure can control a rate (e.g., speed) that the packaged semiconductors are moved between the tube 58 and the magazine 84.

The buffer track 78 can include a packaged semiconductor detector 112 that can detect packaged semiconductors passing across a threshold. Additionally, the packaged semiconductor detector 112 can be configured to detect a jamming of units (e.g., packaged semiconductors) at the entrance or exit of the buffer track 78. Upon a detection of such jamming, the packaged semiconductor detector 112 can provide a jam signal to the controller 54. The controller 54 can be configured to take appropriate action (e.g., disable the pressure differential transfer system 52, activate an alarm, etc.) in response to the jam signal. The packaged semiconductor detector 112 could be implemented, for example, as a photoeye, a Hall Effect sensor or the like. The controller 54 can employ data provided by the packaged semiconductor detector 112 (related to the passing packaged semiconductors) to determine a fill state of tubes 58 and magazines 84.

The differential pressure causes the packaged semiconductors to be transferred between the positioned tube 58 and the positioned compartment 88 over a relatively level (e.g., flat) path of travel. Thus, packaged semiconductors can be transferred without tilting either (or both) of the positioned tube 58 and the positioned magazine 84. Employing the pressure differential transfer system 52 can reduce damage (e.g., bent packaged semiconductor pins or leads, cracked packaged semiconductor casings, etc.) that typically occur from transferring packaged semiconductors between tubes 58 and magazines 84 manually (e.g., employment of a gravitational assistance).

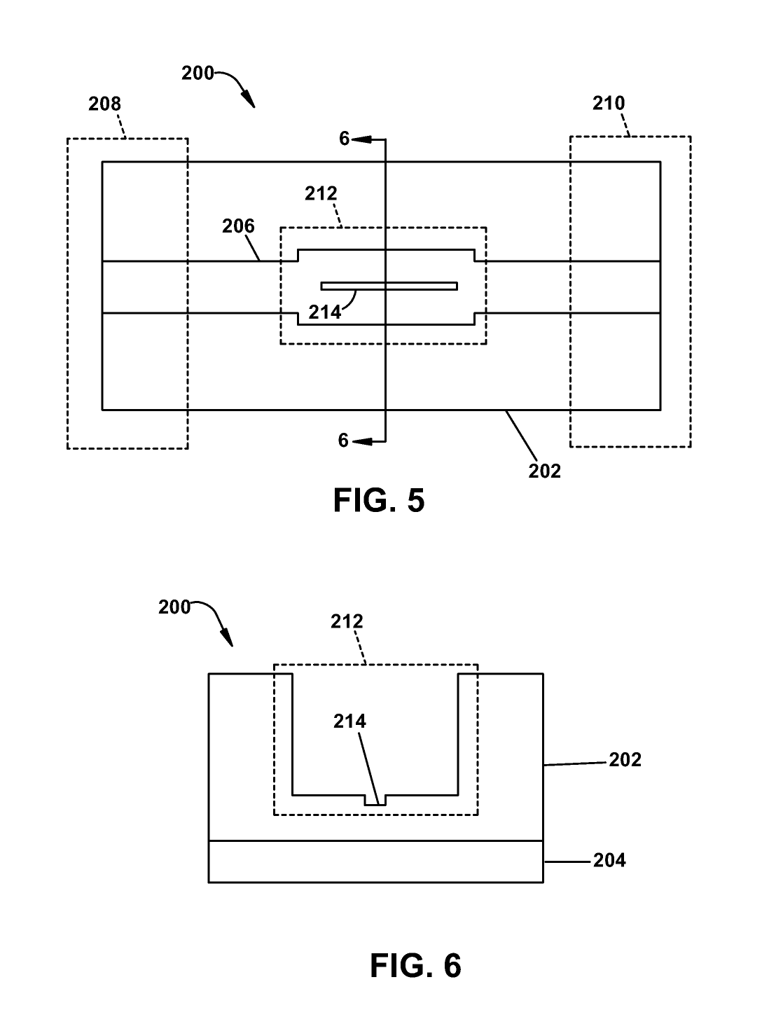

FIGS. 5 and 6 illustrate an example of a buffer track 200 employable by the pressure differential system 52 illustrated in FIGS. 1 and 2 in accordance with an aspect of the invention. FIG. 5 illustrates a top view of the buffer track 200. FIG. 6 illustrates a cross section of the buffer track illustrated in FIG. 5 taken along line 6-6 of FIG. 5. FIGS. 5 and 6 employ the same reference numbers to indicate the same structure. Moreover, for simplification of explanation, not all features of the buffer track 200 are illustrated in both FIGS. 5 and 6. The buffer track 200 can include a top portion 202 and a bottom portion 204. The top portion 202 of the buffer track 200 can include a track section 206 that provides a duct for guiding packaged semiconductors passing across the buffer track 200. As shown in FIG. 8, the track section 206 has a U-shaped cross section, however, one skilled in the art will appreciate that other shapes are possible as well. The buffer track 200 includes a tube end 208 and a magazine end 210. The tube end 208 can be configured to transfer packaged semiconductors to and from a tube (e.g., the tube 150 illustrated in FIG. 3). The magazine end can be configured to transfer packaged semiconductors to and from a compartment of a magazine (e.g., the magazine 170 illustrated in FIG. 4). Thus, a tube can be positioned proximally to the tube end 208, while a magazine can be positioned proximally to the magazine end 210, such that the buffer track 200 facilitates transfers of packaged semiconductors between the tube and a compartment of the magazine.

The buffer track 200 can include, for example an air track section 212 positioned in the track section. The air track section 212 can have a greater width than the rest of the track section 206. Additionally, the air track section 212 can include an air duct 214 to which differential pressure (e.g., force by air-blow, air pressure or vacuum pressure) can be applied, for example by the differential pressure supply 108 illustrated in FIG. 1. Application of the differential pressure can adjust a rate of travel of packaged semiconductors are guided across the buffer track 200.

Referring back to FIGS. 1 and 2, the pressure differential transfer system 52 can also include a user interface 114. The user interface 114 can be implemented, for example, as a graphical user interface, one or more buttons and/or switches or the like. The user interface 114 can be controlled by the controller 54. The interface can include, for example, a magazine loading activation mechanism that causes the pressure differential transfer system 52 to transition from a deactivated state (e.g., an inactive state) to a magazine loading state. The user interface 114 can also include a tube loading activation mechanism that causes the pressure differential transfer system 52 to transition from the deactivated state to a tube loading state. Furthermore, the user interface 114 can include a deactivation mechanism that causes the pressure differential transfer system 52 to transition to the deactivated state from either the tube loading state or the magazine loading state.

If a user of the pressure differential transfer system 52 desires to load magazines 84 with packaged semiconductors, a tube input stack 60 and a magazine input stack 86 can be loaded into the tube input station 56 and the magazine input station 82, respectively. Initially, in the present example, all of the packaged semiconductors will be in tubes 58 of the tube input stack 60. Once the tube input stack 60 and the magazine input stack 86 are loaded at their respective input stations 56 and 82, the magazine loading mechanism can be actuated thereby causing the pressure differential transfer system 52 to transition to the magazine loading state. In the magazine loading state, the tube indexer 74 conveys (e.g., singulates) a first tube 58 (e.g., the lowest tube 58) of the tube input stack 60 to the tube transfer station 79. Upon the conveyance of the first tube 58, the remaining tubes 58 in the tube input stack 60 are lowered by the tube lowering mechanism. Additionally, the magazine indexer 102 conveys (e.g., singulates) a first magazine 84 (e.g., the lowest magazine 84) of the magazine input stack 86 such that a first compartment 88 of the magazine 84 is conveyed to the magazine transfer station 105. Upon conveyance of the first magazine 84, the remaining magazines 84 in the magazine input stack 86 can be lowered by the magazine lowering mechanism.

When the first tube 58 and the first compartment 88 are conveyed to the tube and magazine transfer stations 79 and 105 of the buffer track 78, the differential pressure moves packaged semiconductors from the tube 58 to the first compartment 88 of the first magazine 84. The packaged semiconductor detector 112 and the controller 54 can be employed to determine a fill state of the first compartment 88 of the first magazine 84. If the controller 54 determines that the first compartment 88 of the first magazine 84 is full, the magazine indexer 102 can reposition the first magazine 84 such that a second compartment 88 of the first magazine 84 is positioned at the magazine transfer station 105. If the controller 54 determines that the first compartment 88 of the first magazine 84 is not full (and thus can receive additional packaged semiconductors) and that the first tube 58 is empty, the tube indexer 74 can convey the first tube 58 to the tube output station 66 and a second tube 58 from the tube input stack 60 to the tube transfer station 79. Upon receipt of the first tube 58, the tube output station 66 can add the first tube 58 to a tube output stack 68. Thus, packaged semiconductors from the second tube 58 can be transferred to the first compartment 88 of the first magazine 84 with application of the differential pressure. Packaged semiconductors from the tubes 58 can be transferred into the first compartment 88 of the first magazine 84 until the controller 54 determines that the first compartment 88 of the first magazine 84 is full.

Upon a determination that the first compartment 88 of the first magazine 84 is full, the magazine indexer 102 can position a second compartment 88 of the first magazine 84 at the magazine transfer station 105. The second compartment 88 of the first magazine 84 can thus be filled with packaged semiconductors in a manner similar to the first compartment 88 of the first magazine 84. This process can be repeated until all compartments 88 of the first magazine 84 are full.

Upon detection that all compartments 88 of the first magazine 84 are full, the magazine indexer 102 can convey the first magazine 84 to the magazine output station 94. Upon receipt of the first magazine 84, the magazine output station 94 can add the first magazine 84 to a magazine output stack 96. Additionally, the magazine indexer 102 can convey a second magazine 84 of the magazine input stack 86 such that a first compartment 88 of the second magazine 84 is positioned at the magazine transfer station 105. Thus, the second magazine 84 can be filled with packaged semiconductors in a manner similar to the first magazine 84. Once the second magazine 84 is filled with packaged semiconductors, the second magazine 84 can be conveyed to the magazine output station 94 and added to the magazine output stack 96. This process can be repeated until either all the magazines 84 in the magazine input stack 86 are full, and/or until all of the tubes 58 in the tube input stack 60 are empty. Upon a determination that all of the magazines 84 in the magazine input stack 86 are full and/or all of the tubes 58 in the tube input stack 60 are empty, the pressure differential transfer system 52 can transition to the deactivated state.

When the magazines 84 are filled with the packaged semiconductors, magazines 84 in the magazine output stack 96 can be removed by the user of the pressure differential transfer system 52. In one example, the magazines 84 in the magazine output stack 96 can be loaded into a packaged semiconductor oven for a baking process. Such packaged semiconductor ovens can have a rack that can, for example store a plurality of magazines 84 (e.g., the magazine output stack 96) such that many packaged semiconductors can be baked at the same time.

Alternatively, if the user of the pressure differential transfer system 52 desires to transfer packaged semiconductors from magazines 84 to tubes 58, the user can place a magazine input stack 86 at the magazine input station 82 and a tube input stack 60 at the tube input station 56. In such a situation, the magazines 84 in the magazine input stack 86 can be filled with packaged semiconductors. The user can actuate the tube loading mechanism, thus transitioning the pressure differential transfer system 52 to the tube loading state. In the tube loading state, a first magazine 84 (e.g., the lowest magazine 84) from the magazine input stack 86 can be conveyed (e.g., singulated) by the magazine indexer 102 such that a first compartment 88 of the first magazine 84 is positioned at the magazine transfer station 105. Additionally, a first tube 58 in the tube input stack 60 (e.g., the lowest tube 58) can be conveyed (e.g., singulated) by the tube indexer 74 such that the first tube 58 is conveyed to the tube transfer station 79.

When both the first tube 58 and the first magazine 84 are correctly positioned, the differential pressure supply 108 can supply differential pressure (e.g., force by air-blow, air pressure or vacuum pressure) that causes packaged semiconductors in the first compartment 88 of the first magazine 84 to be transferred to the first tube 58. The packaged semiconductor detector 112 and the controller 54 can be employed to determine a fill state of the compartment 88 of the magazine 84 and the tube 58. If the controller 54 determines that the first tube 58 is full, the tube indexer 74 can convey the first tube 58 to the tube output station 66. Upon receipt of the first tube 58, the tube output station 66 can add the first tube 58 to a tube output stack 68. Additionally, the tube indexer 74 can convey a second tube 58 of the tube input stack 60 to the tube transfer station 79. This process can be repeated until the first compartment 88 of the first magazine 84 is emptied.

Upon a determination that the first compartment 88 of the first magazine 84 is empty, the magazine indexer 102 can reposition the first magazine 84 such that a second compartment 88 of the first magazine 84 is positioned at the magazine transfer station 105, and the second compartment 88 of the first magazine 84 can be emptied in a manner similar to the first compartment 88 of the first magazine 84. This process can be repeated until the entire first magazine 84 is emptied. When it is determined that the first magazine 84 is emptied, the first magazine 84 can be conveyed to the magazine output station 94. Upon receipt of the first magazine 84, the magazine output station 94 can add the first magazine 84 to a magazine output stack 96. Additionally, a second magazine 84 from the magazine input stack 86 can be conveyed such that a first compartment 88 of the second magazine 84 is positioned at the magazine transfer station 105. The second magazine 84 can thus be emptied in a manner similar to the first magazine 84. This process can be repeated until all magazines 84 in the magazine input stack 86 are emptied, and/or until all tubes 58 in the tube input stack 60 are filled. Upon a determination that all magazines 84 in the magazine input stack 86 are emptied, and/or all tubes 58 in the tube input stack 60 are filled, the pressure differential transfer system 52 can transition to the deactivated state.

When the packaged semiconductors have been transferred to the tubes 58, filled tubes 58 in the tube output stack 68 can be removed by the user of the pressure differential transfer system 52. The filled tubes 58 can be transferred, for example, to a pick and place machine that attaches the packaged semiconductors to a printed circuit board. Alternatively, the filled tubes 58 could be shipped to a separate facility and/or machine for further processing and/or testing.

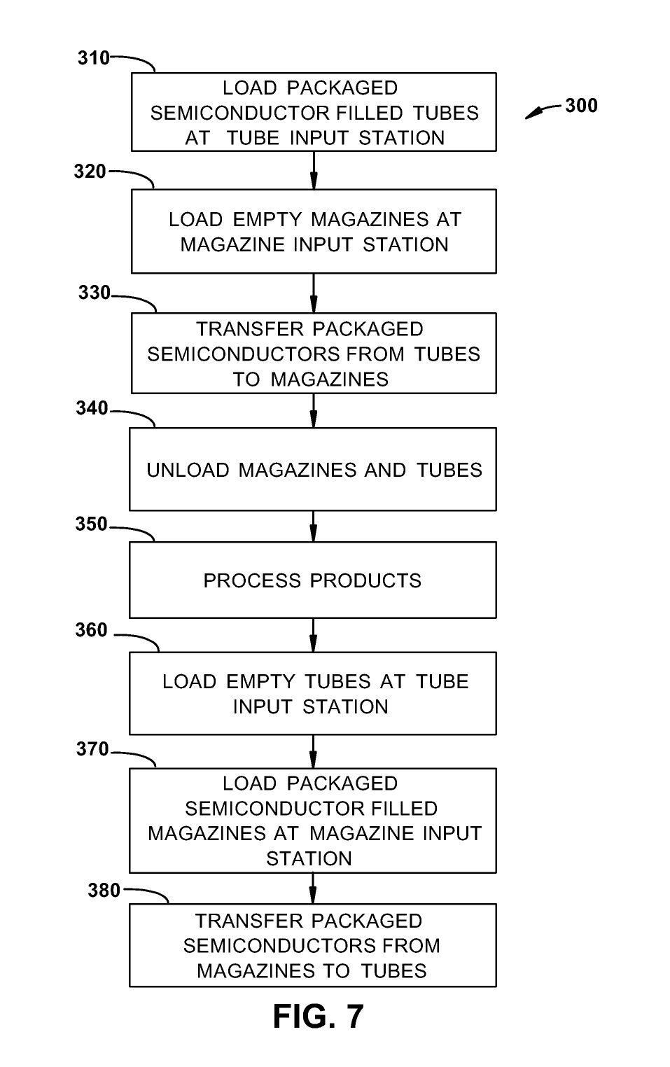

In view of the foregoing structural and functional features described above, methodologies will be better appreciated with reference to FIG. 7 It is to be understood and appreciated that the illustrated actions, in other embodiments, may occur in different orders and/or concurrently with other actions. Moreover, not all illustrated features may be required to implement a method.

FIG. 7 illustrates a flow chart for a methodology 300 for transferring packaged semiconductors between packaged semiconductor storage mediums in accordance with an aspect of the invention. In the present example, the storage mediums can be implemented as tubes (e.g., the tube 150 illustrated in FIG. 3) and magazines (e.g., the magazine 170 illustrated in FIG. 4). The methodology 300 can be performed, for example with a differential pressure transfer system (e.g., the differential pressure transfer system 52 illustrated in FIGS. 1 and 2). At 310, packaged semiconductors filled tubes are loaded at a tube input station of the pressure differential transfer system, thereby providing a first tube input stack. The tubes could be implemented, for example, as the tube 150 illustrated in FIG. 3. At 320, empty magazines are loaded at a magazine input station of the pressure differential transfer system, thereby providing a first magazine input stack. The magazines could be implemented, for example, as the magazine 170 illustrated in FIG. 4.

At 330, packaged semiconductors are transferred from the tubes to the magazines with the application of a differential pressure (e.g., force by air-blow, air pressure, vacuum pressure, etc.). To transfer the packaged semiconductors, the first magazine input stack can be indexed. Indexing of the first magazine input stack can include conveyance (e.g., singulation) or repositioning of a given magazine to a buffer track of the pressure differential transfer system such that an empty compartment of the given magazine is positioned proximally to a magazine end (a magazine section) of the buffer track, which can be referred to as a magazine transfer station. Upon filling all compartments of the given magazine, the given magazine can be conveyed to a magazine output station of the pressure differential transfer system, where the given magazine can be added to a first magazine output stack. Additionally, to transfer the packaged semiconductors, the tube input stack can also be indexed. Indexing of the tube input stack can include conveyance (e.g., singulation) of a given tube in the first tube input stack to a position proximally to a tube end (e.g., a tube section) of the buffer track, which can be referred to as a tube transfer station. Upon emptying the given tube, the given tube can be conveyed to a tube output station of the pressure differential transfer system, where the given tube can be added to a first tube output stack. The buffer track could be implemented, for example, as the buffer track 200 illustrated in FIGS. 5 and 6.

At 340, packaged semiconductor filled magazines and emptied tubes can be unloaded at the respective magazine and tube output stations. At 350, the packaged semiconductors can be processed. Processing of the packaged semiconductors can include, for example, a baking of the packaged semiconductors in the packaged semiconductor filled magazines.

After processing, it may be desirable to transfer the packaged semiconductors from the magazine back to tubes. Thus, at 360, empty tubes can be loaded at the tube input station, thereby forming a second tube input stack. At 370, the packaged semiconductor filled magazines can be loaded at the magazine input station, thereby forming a second magazine input stack. At 380, the packaged semiconductors are transferred from the filled magazines to the empty tubes. To transfer the packaged semiconductors, the second magazine input stack can be indexed. Indexing of the second magazine input stack can include conveyance (e.g., singulation) or repositioning of a given magazine of the second magazine input stack to the buffer track such that a packaged semiconductor filled compartment of the given magazine is conveyed to the magazine transfer station. Upon emptying of the given magazine, the given magazine can be conveyed to a magazine output station and added to a second magazine output stack. Additionally, to transfer the packaged semiconductors, the second tube input stack can also be indexed. Indexing of the second tube input stack can include conveyance (e.g., singulation) of a given tube in the second tube input stack to the tube transfer station. Upon filling the given tube, the given tube can be conveyed to the tube output station and can be added to a second tube output stack.

What have been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications, and variations that fall within the scope of the appended claims.

What is claimed is:

1. A system for transferring packaged semiconductors comprising:
a first input station configured to receive one or more storage mediums of a first type configured to store packaged semiconductors;
a second input station configured to receive one or more storage mediums of a second type configured to store packaged semiconductors;
a differential pressure supply to provide a differential pressure that moves packaged semiconductors between a given storage medium of the first type and a given storage medium of the second type.

2. The system of claim 1, further comprising a buffer track that facilitates transfer for the packaged semiconductors between the given storage medium of the first type and the given storage medium of the second type.

3. The system of claim 2, the buffer track comprising:
a first end configured to transfer packaged semiconductors to and from a storage medium of the first type; and
a second end configured to transfer packaged semiconductors to and from a storage medium of the second type.

4. The system of claim 3, wherein:
the first input station is a tube input station;
the second input station is a magazine input station;
the one or more storage mediums of the first type are one or more tubes; and
the one or more storage mediums of the second type are one or more magazines.

5. The system of claim 4, further comprising:
a tube indexer configured to convey a given tube from the tube input station to a tube transfer station and a tube output station;
a magazine indexer configured to convey a given magazine from the tube input station to a magazine transfer station and a magazine output station.

6. The system of claim 4, wherein the one or more magazines are at least two magazines, each magazine comprising a plurality of compartments for storing a plurality of packaged semiconductors.

7. The system of claim 6, wherein:
the at least one tube comprises at least one plastic tube; and
the at least two magazines comprise at least two metallic magazines.

8. A system for transferring a plurality of packaged semiconductors comprising:
means for receiving a plurality of packaged semiconductor storage mediums of a first type;
means for receiving a plurality of semiconductor storage mediums of a second type; and
means for providing a differential pressure that transfers the plurality of packaged semiconductors between the plurality of semiconductor storage mediums of the first type and the plurality of semiconductor storage mediums of the second type.

9. The system of claim 8, further comprising means for guiding the plurality packaged semiconductors between semiconductor storage mediums of the first type and the plurality of semiconductor storage mediums of the second type.

10. The system of claim 9, further comprising means for determining a fill state of the plurality of storage mediums of the first type and the plurality of storage mediums of the second type.

11. A method for transferring a plurality of packaged semiconductors, the method comprising:
loading a plurality of first packaged semiconductor storage mediums at a first input station, thereby forming a first input stack, wherein the plurality of first packaged semiconductor storage mediums contain the plurality of packaged semiconductors;
loading a plurality of second packaged semiconductor storage mediums at a second input station, thereby forming a second input stack; and
transferring the plurality of packaged semiconductors from the plurality of first semiconductor storage mediums to the plurality of second packaged semiconductor storage mediums with an application of a differential pressure.

12. The method of claim 11, further comprising:
conveying the first packaged semiconductor storage mediums at the first input station to a first output station, thereby forming a first output stack; and
conveying the second packaged semiconductor storage mediums at the second input station to a second output station, thereby forming a second output stack.

13. The method of claim 12, wherein:
the plurality of first storage mediums are a plurality of tubes; and
the plurality of second storage mediums are a plurality of magazines.

14. The method of claim 13, wherein each magazine of the plurality of magazines includes a plurality of compartments for storing packaged semiconductors.

15. The method of claim 14, further comprising indexing the second input stack in response to a detection that a given compartment in a given magazine of the second input stack is filled.

16. The method of claim 13, wherein the packaged semiconductors are guided across a buffer track that adapts an end of a given magazine of the plurality of magazines to an end of a given tube of the plurality of tubes.

17. The method of claim 16, wherein:
the plurality of tubes are plastic tubes; and
the plurality of magazines are metallic magazines.

18. The method of claim 11, wherein:
the plurality of first storage mediums are a plurality of magazines; and
the plurality of second storage mediums are a plurality of tubes.

19. The method of claim 18, wherein each magazine of the plurality of magazines includes a plurality of compartments for storing packaged semiconductors.

20. The method of claim 18, further comprising indexing the first input stack upon detection that a given compartment in a given magazine of the first input stack is emptied.

21. The method of claim 18, wherein the packaged semiconductors are guided across a buffer track that adapts an end of a given magazine of the plurality of magazines to an end of a given tube of the plurality of magazines.

22. The method of claim 21, further comprising indexing the second input stack upon detection that the given tube of the second input stack is filled.
